(19) United States
(12) Patent Application Publication
(10) Pub. No.: US 2024/0061972 A1
(43) Pub. Date: Feb. 22, 2024

(54) METHOD AND APPARATUS WITH PERFORMANCE MODELING

(71) Applicants: SAMSUNG ELECTRONICS CO., LTD., Suwon-si (KR); Seoul National University R&DB Foundation, Seoul (KR)

(72) Inventors: Hyung-Dal KWON, Suwon-si (KR); Byeonghyun KO, Seoul (KR); Seongbeom KIM, Suwon-si (KR); Jaejin LEE, Seoul (KR); Gyeongje CHO, Seoul (KR)

(73) Assignees: SAMSUNG ELECTRONICS CO., LTD., Suwon-si (KR); Seoul National University R&DB Foundation, Seoul (KR)

(21) Appl. No.: 18/181,604

(22) Filed: Mar. 10, 2023

(30) Foreign Application Priority Data
Aug. 16, 2022 (KR) 10-2022-0102219

(51) Int. Cl. G06F 30/20

(52) U.S. Cl. CPC G06F 30/20

(57) ABSTRACT

An apparatus for modelling a computing system including a processor configured to generate a plurality of classes related to properties of a computing system based on received information related to a first hardware of the computing system, generate a profile result based on the plurality of classes, and predict a performance of second hardware in the computing system in place of the first hardware, the prediction being based on the profile result.

### CROSS-REFERENCE TO RELATED APPLICATIONS

This application claims the benefit under 35 USC § 119(a) of Korean Patent Application No. 10-2022-0102219, filed on Aug. 16, 2022, at the Korean Intellectual Property Office, the entire disclosure of which is incorporated herein by reference for all purposes.

### BACKGROUND

### 1. Field

The following description relates to a method and apparatus with performance modeling.

### 2. Description of Related Art

Typically, a large scale computing system may be modelled to determine its performance using a simulator or an analytic model.

In an analysis modeling approach, an execution time of each operation is measured using a profiling result. In this approach, prediction of workload performance for a plurality of nodes can use only one node.

The analysis modeling approach derives an execution time with a formula, and then predicts a total execution time by accumulating the derived execution time. The analysis modeling method does not perform actual calculations, e.g., by modifying library code used in the workload, to derive the execution time.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a computing apparatus includes a processor configured to generate a plurality of classes related to properties of a computing system based on received information related to a first hardware of the computing system, generate a profile result based on the plurality of classes, and predict a performance of second hardware in the computing system in place of the first hardware, wherein the prediction is based on the profile result.

The information may include driving frequency, a peak performance, a cache memory capacity, a cache memory bandwidth, a memory frequency, a memory capacity, a memory bandwidth, a storage capacity, a storage bandwidth of the first hardware, a bandwidth between the first hardware and other hardware, a bandwidth between the first hardware and a memory, and/or a network bandwidth.

For the prediction of the performance of the second hardware, the processor is configured to predict the performance of the second hardware based on a performance curve of a roofline model corresponding to the first hardware according to the profile result, a utilization of the first hardware, and an operational intensity of an operation to be processed.

For the prediction of the performance of the second hardware, the processor may be configured to calculate a target utilization based on the utilization of the first hardware and the operational intensity and predict the performance of the second hardware based on the target utilization and the performance curve of the roofline model.

For the prediction of the performance of the second hardware, the processor may be configured to predict the performance of the second hardware by performing interpolation or extrapolation based on the target utilization and the performance curve of the roofline model.

For the prediction of the performance of the second hardware, the processor may be configured to calculate an operation execution time of multiple nodes, of a plurality of nodes corresponding to different operations, of a tree structure, an operation of which having been performed by the second hardware.

For the prediction of the performance of the second hardware, the processor may be configured to calculate a first changed time by changing an operation execution time of a lower node of the multiple nodes, calculate a second changed time by changing an operation execution time of a sibling node of the multiple nodes based on the first changed time, and calculate the operation execution time by changing an operation execution time of an upper node of the multiple nodes based on the second changed time.

For the prediction of the performance of the second hardware, the processor may be configured to extend an execution time of a first node among the multiple nodes responsive to an addition of a new operation to the plurality of nodes and calculate the operation execution time by inserting the new operation between an operation of a second node, of the multiple nodes, that performs an operation prior to the first node and an operation of the first node.

For the prediction of the performance of the second hardware, the processor may be configured to determine a start time of an operation corresponding to the multiple nodes based on a causal relationship of the operations between the multiple nodes.

For the prediction of the performance of the second hardware, the processor may be configured to determine a start time of an operation corresponding to child nodes, of the multiple nodes, based on a start time of an operation corresponding to a parent node, of the multiple nodes, and a causal relationship between the child nodes of the parent node.

In a general aspect, a processor-implemented method includes generating a plurality of classes related to properties of a computing system based on information related to a first hardware of the computing system, performing profiling based on the plurality of classes, and predicting performance of second hardware in the computing system in place of the first hardware, wherein the predicting is based on the profiling.

The information may include driving frequency, peak performance, cache memory capacity, cache memory bandwidth, memory frequency, memory capacity, memory bandwidth, storage capacity, storage bandwidth of the first hardware, bandwidth between the first hardware and other hardware, bandwidth between the first hardware and memory, and/or network bandwidth.

The predicting may include predicting the performance of the second hardware based on a performance curve of a roofline model corresponding to the first hardware according to the profiling, a utilization of the first hardware, and an operational intensity of an operation to be processed.

The predicting of the performance of the second hardware may include calculating a target utilization based on the utilization of the first hardware and the operational intensity and predicting the performance of the second hardware based on the target utilization and the performance curve of the roofline model.

The predicting of the performance of the second hardware may include predicting the performance of the second hardware by performing interpolation or extrapolation based on the target utilization and the performance curve of the roofline model.

For the predicting the performance of the second hardware, the predicting may include calculating an operation execution time of multiple nodes, of a plurality of nodes, of a tree structure, an operation of which having been performed by the second hardware.

The calculating of the operation execution time of the multiple nodes may include calculating a first changed time by changing an operation execution time of a lower node of the multiple nodes, calculating a second changed time by changing an operation execution time of a sibling node of the multiple nodes based on the first changed time, and calculating the operation execution time by changing an operation execution time of an upper node of the multiple nodes based on the second changed time.

The calculating of the operation execution time of the multiple nodes may include extending an execution time of a first node among the multiple nodes responsive to an addition of a new operation to the plurality of nodes and calculating the operation execution time by inserting the new operation between an operation of a second node, of the multiple nodes, that performs an operation prior to the first node and an operation of the first node.

The calculating of the operation execution time of the plurality of nodes may include determining a start time of an operation corresponding to the multiple nodes based on a causal relationship of the operations between the multiple nodes.

The calculating of the operation execution time of the plurality of nodes may include determining a start time of an operation corresponding to child nodes, of the multiple nodes, based on a start time of an operation corresponding to a parent node, of the multiple nodes, and a causal relationship between the child nodes of the parent node.

In a general aspect, a processor-implemented method includes generating a first performance profile based on a first plurality of attributes of a first configuration of a computing system and interpolating and extrapolating a new performance profile for a new configuration within the computing system, wherein the interpolating and extrapolating are based on an applying of the first performance profile to the new configuration.

The interpolating and extrapolating of the new performance profile may be based on a performance curve of a roofline model corresponding to the first performance profile, a utilization of the first configuration, and an operational intensity of an operation to be processed by the new configuration.

Other features and aspects will be apparent from the following detailed description, the drawings, and the claims.

### BRIEF DESCRIPTION OF THE DRAWINGS

FIG. 1 illustrates an example of a computing apparatus, according to one or more embodiments.

FIG. 2 illustrates an example of a process performance modeling to predict a performance, according to one or more embodiments.

FIG. 3 illustrates an example of predicting performance by adding information related to hardware to a profile result, according to one or more embodiments.

FIG. 4 illustrates an example of a roofline model for predicting a performance of second hardware, according to one or more embodiments.

FIG. 5 illustrates an example of a roofline model for predicting performance of second hardware, according to one or more embodiments.

FIG. 6 illustrates an example of a process of calculating an operation time by rearranging the operations, according to one or more embodiments.

FIG. 7 illustrates an example of a process of inserting an operation, according to one or more embodiments.

FIG. 8 illustrates an example of a process of aligning an operation, according to one or more embodiments.

FIG. 9 illustrates an example of an implementation performance modeling, according to one or more embodiments.

FIGS. 10A to 10D illustrate examples of computing apparatuses and systems with performance modeling, according to one or more embodiments.

FIG. 11 illustrates an example of a method of predicting a performance of a computing system, according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C’, and the like are intended to have disjunctive meanings, and these phrases “at least one of A, B, and C”, “at least one of A, B, or C’, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

As used in connection with various example embodiments of the disclosure, any use of the terms “module” or “unit” means hardware and/or processing hardware configured to implement software and/or firmware to configure such processing hardware to perform corresponding operations, and may interchangeably be used with other terms, for example, “logic,” “logic block,” “part,” or “circuitry”. As one non-limiting example, an application-predetermined integrated circuit (ASIC) may be referred to as an application-predetermined integrated module. As another non-limiting example, a field-programmable gate array (FPGA) or an application-specific integrated circuit (ASIC) may be respectively referred to as a field-programmable gate unit or an application-specific integrated unit. In a non-limiting example, such software may include components such as software components, object-oriented software components, class components, and may include processor task components, processes, functions, attributes, procedures, subroutines, segments of the software. Software may further include program code, drivers, firmware, microcode, circuits, data, database, data structures, tables, arrays, and variables. In another non-limiting example, such software may be executed by one or more central processing units (CPUs) of an electronic device or secure multimedia card.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As noted above, in a typical analysis modeling approach a prediction of workload performance for a plurality of nodes can only consider one node, derives an execution time with a formula, and then predicts a total execution time by accumulating the derived execution time, without performing actual calculations of the workload, e.g., by modifying library code used in the workload, to derive the execution time.

However, since this prediction approach entails an actual code execution process even when using modified library code, the execution time may increase linearly according to the target number of nodes. In addition, a simulation framework tool may be applied to create an environment capable of predicting the performance, which may increase the cost and make it necessary to perform modeling for each component of a node required to perform a simulation. Thus, these typical approaches are costly in processing, time, and energy resources.

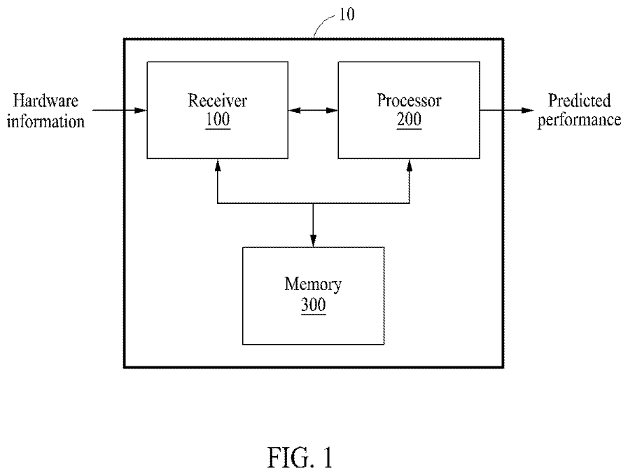

FIG. 1 illustrates an example of a computing apparatus, according to one or more embodiments.

Referring to FIG. 1, a computing apparatus 10 may model the performance of a computing system. The computing apparatus 10 may predict the performance of the computing system by using a modeling result.

The computing apparatus 10 may be, or be included in, a personal computer (PC), a data server, or a portable device, as non-limiting examples.

The portable device may include, for example, a laptop computer, a mobile phone, a smartphone, a tablet PC, a mobile Internet device (MID), a personal digital assistant (PDA), an enterprise digital assistant (EDA), a digital still camera, a digital video camera, a portable multimedia player (PMP), a personal or portable navigation device (PND), a handheld game console, an e-book, or a smart device, as non-limiting examples. The smart device may be, for example, a smartwatch, a smart band, or a smart ring, as non-limiting examples.

The computing system may be composed of a plurality of hardware, for example. The hardware may include computing hardware and/or storage hardware.

The computing hardware may include various types of processors. The computing hardware may include, for example, a CPU, a graphics processing unit (GPU), a neural processing unit (NPU), a tensor processing unit (TPU), or an FPGA, as non-limiting examples.

The computing hardware may perform various operations. The computing hardware may perform deep learning computations through machine learning, e.g., using a machine learning models such as neural networks, as a non-limiting examples.

Such a neural network may generally refer to a machine learning model having a problem-solving ability implemented through artificial neurons or nodes forming a network through synaptic connections where a strength of the synaptic connections is changed through training.

The nodes of the neural network may include a combination of weights or biases. The neural network may include one or more layers, each including one or more nodes. In one example, a neural network may be trained to infer a result from an unknown input by using predetermined training inputs and iteratively changing the weights with respect to plural nodes of one or more layers through training, such as through backpropagation training.

The neural network may include a deep neural network (DNN). The neural network may include a convolutional neural network (CNN), a recurrent neural network (RNN), a perceptron, a multiplayer perceptron, a feed forward (FF), a radial basis network (RBF), a deep feed forward (DFF), a long short-term memory (LSTM), a gated recurrent unit (GRU), an auto encoder (AE), a variational auto encoder (VAE), a denoising auto encoder (DAE), a sparse auto encoder (SAE), a Markov chain (MC), a Hopfield network (HN), a Boltzmann machine (BM), a restricted Boltzmann machine (RBM), a deep belief network (DBN), a deep convolutional network (DCN), a deconvolutional network (DN), a deep convolutional inverse graphics network (DCIGN), a generative adversarial network (GAN), a liquid state machine (LSM), an extreme learning machine (ELM), an echo state network (ESN), a deep residual network (DRN), a differentiable neural computer (DNC), a neural turning machine (NTM), a capsule network (CN), a Kohonen network (KN), and an attention network (AN), as non-limiting examples.

The storage hardware may include a memory, or other non-transitory computer-readable storage media.

The computing apparatus 10 may include a receiver 100 and a processor 200. The computing apparatus 10 may also include a memory 300.

The receiver 100 may obtain or receive information about the hardware that makes up the computing system. This hardware information may include information about the hardware's driving frequency, peak performance, cache memory capacity, cache memory bandwidth, memory frequency, memory capacity, memory bandwidth, storage capacity, storage bandwidth, bandwidth between hardware and other hardware, bandwidth between hardware and memory, and/or network bandwidth, as non-limiting examples.

Hereinafter, hardware may refer to either one of a first hardware or a second hardware. The first hardware may be hardware capable of measuring a performance or hardware that has a known performance level. The second hardware may be the target hardware whose performance needs to be predicted because its performance cannot be measured. In some examples, it may be desired to estimate a performance, e.g., performance profile, for the second hardware.

The receiver 100 may include, and is representative of, a receiving interface. The receiver 100 may output or transmit the information related to hardware to the processor 200. The receiver may include, and is representative of, a transceiver interface, which may output or transmit instructions and/or other information to the second hardware for obtaining or receiving any of the information, and/or for commanding or requesting the second hardware to collect or update such information. The receiver may further receive or transmit initiation or scheduling instructions from/to the second hardware to initiate the execution of the prediction of the performance of the second hardware.

The processor 200 may process data stored in the memory 300 and the information transmitted from the receiver 100. The processor 200 may execute a computer-readable code (e.g., instructions or software) stored in the memory 300 and instructions triggered by the processor 200.

The processor 200 may be a hardware-implemented data processing device having a circuit that is physically structured to execute desired operations. As a non-limiting example, such desired operations may include, for example, code or instructions included in a program.

For example, the hardware-implemented data processing device may include a microprocessor, a CPU, a processor core, a multi-core processor, a multiprocessor, an application-specific integrated circuit (ASIC), and an FPGA, as non-limiting examples.

The processor 200 may generate a node and an edge class for a plurality of operations related to an attribute of the computing system based on information related to the first hardware. The processor 200 may generate a profile of the first hardware by profiling an operation being executed. The processor 200 may also generate the profile by profiling the operation based on a plurality of classes.

The processor 200 may predict a performance profile for the second hardware where the second hardware would be employed in place of the first hardware in the computing system and where the second hardware's performance is predicted based on the profile result of the first hardware.

The processor 200 may predict the performance profile of the second hardware based on performance curve of a roofline model corresponding to the first hardware according to the profile result. The roofline model may provide a performance curve that may be used to predict a performance profile of the second hardware. In addition, the processor may also be configured to use a utilization of the first hardware and an operational intensity of an operation to be processed by the second hardware to predict the second hardware's performance profile or performance at a certain operating point.

The processor 200 may calculate a target utilization based on the utilization of the first hardware and the operational intensity. The processor 200 may predict the performance of the second hardware based on the target utilization and a performance curve of the roofline model.

The processor 200 may predict the performance of the second hardware based on the target utilization and the performance curve of the roofline model.

The processor 200 may predict the performance of the second hardware by performing interpolation or extrapolation based on the target utilization and the performance curve of the roofline model.

The second hardware may perform an operation based on a tree structure including a plurality of nodes corresponding to different operations. The processor 200 may calculate an operation execution time of the plurality of nodes based on the tree structure including the plurality of nodes.

The processor 200 may calculate a first changed time by changing an operation execution time of a lower node of the tree structure. The processor 200 may calculate a second changed time by changing an operation execution time of a sibling node based on the first changed time. The processor 200 may calculate the operation execution time by changing an operation execution time of an upper node based on the second changed time.

When an additional operation is present, the processor 200 may extend the execution time of the first node among the plurality of nodes. The processor 200 may calculate the operation execution time by inserting the additional operation between an operation of a second node that performs an operation prior to the first node and an operation of the first node.

The processor 200 may determine a start time of an operation corresponding to the plurality of nodes based on a causal relationship of the operations between the plurality of nodes. The processor 200 may determine a start time of an operation corresponding to child nodes based on a start time of an operation corresponding to a parent node included in the plurality of nodes and a causal relationship between the child nodes of the parent node.

The memory 300 may store data for an operation or an operation result. The memory 300 may also store instructions (or programs) executable by the processor 200, which by execution of the instructions the processor 200 is a configured to perform one or more or all operations or methods described herein. For example, the instructions may include instructions for executing an operation of the processor 200 and/or instructions for performing one or more operations of one or more or all components of the processor 200.

The memory 300 may be a volatile memory device or a non-volatile memory device. The volatile memory device may be one or more of any of a dynamic random-access memory (DRAM), a static random-access memory (SRAM), a thyristor RAM (T-RAM), a zero capacitor RAM (Z-RAM), or a twin transistor RAM (TTRAM). The non-volatile memory device may be an electrically erasable programmable read-only memory (EEPROM), a flash memory, a magnetic RAM (MRAM), a spin-transfer torque (STT)-MRAM, a conductive bridging RAM (CBRAM), a ferroelectric RAM (FeRAM), a phase change RAM (PRAM), a resistive RAM (RRAM), a nanotube RRAM, a polymer RAM (PoRAM), a nano floating gate Memory (NFGM), a holographic memory, a molecular electronic memory device, and/or an insulator resistance change memory, as non-limiting examples.

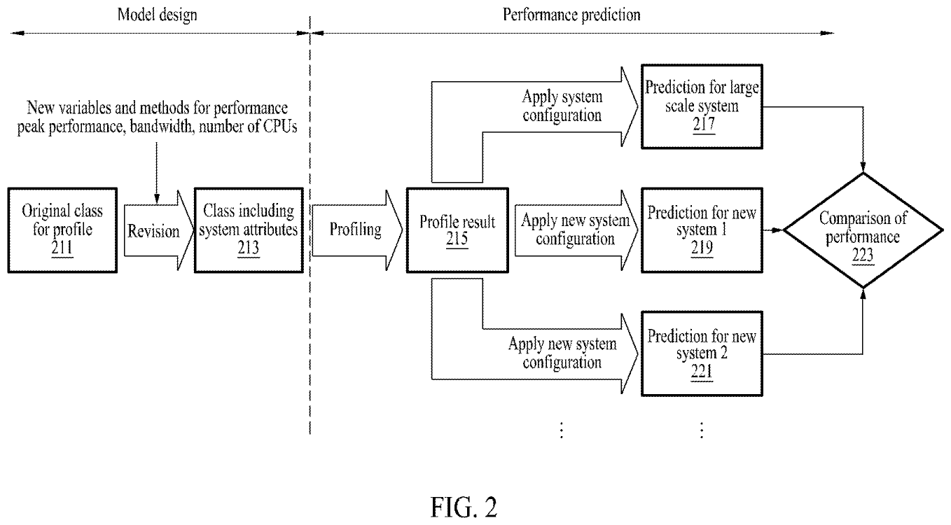

FIG. 2 illustrates an example of a process in which the computing apparatus of FIG. 1 predicts a performance of the second hardware, according to one or more embodiments.

Referring to FIG. 2, a processor (e.g., the processor 200 of FIG. 1) may design a model for predicting a performance of a computing system. The processor 200 may execute a prediction of a performance profile of the computing system based on the designed model.

The processor 200 may generate a class 213 including system attributes by modifying an original class 211 for a profile based on peak performance, bandwidth, or number of CPUs. The processor may perform a revision on the original class 211 to generate the class 213. The revision may be based on new variables and a new method for predicting performance. The revision may consider new variables such as newly measured peak performance, new system bandwidths, and the effect of a different numbers of CPUs in the hardware.

The processor 200 may generate a profile result 215 by performing profiling based on the class 213 including the system attributes.

The processor 200 may store the profile result 215 in a tree-type data structure. The processor 200 may model the performance of the computing system by adding information related to hardware performance to the tree-type data structure.

The processor 200 may apply a formula capable of calculating hardware specifications and performance to a plurality of operations that make up a workload expressed in a tree form to derive peak performance, real performance, a performance curve, a performance profile, utilization, a peak bandwidth, and/or an actual bandwidth, as non-limiting examples.

The processor 200 may perform a scale-out of a node corresponding to the hardware of the computing system by using the derived performance information, calculate the performance of the computing system configured with changed hardware when the hardware specification is changed, and compare the calculation results.

The processor 200 may predict the performance profile of the computing system configured with new hardware based on the profile result 215. In one example, the new performance profile may be derived from changing from a known hardware arrangement (i.e., the first hardware) to a new hardware arrangement (i.e., the second hardware).

The processor 200 may predict 217 a performance of a large scale system by applying the profile result 215 to a large system configuration. The processor 200 may predict 219 a performance of a new system 1 by applying the profile result 215 to a new system configuration. The processor 200 may predict 221 a performance of a new system 2 by applying the profile result 215 to the new system configuration. Likewise, the processor 200 may predict a performance profile for various computing systems based on the profile results. The processor 200 may compare 223 the predicted performance. The comparison 223 may provide a user with an insight of which new system, 1 or 2, provides a better performance profile.

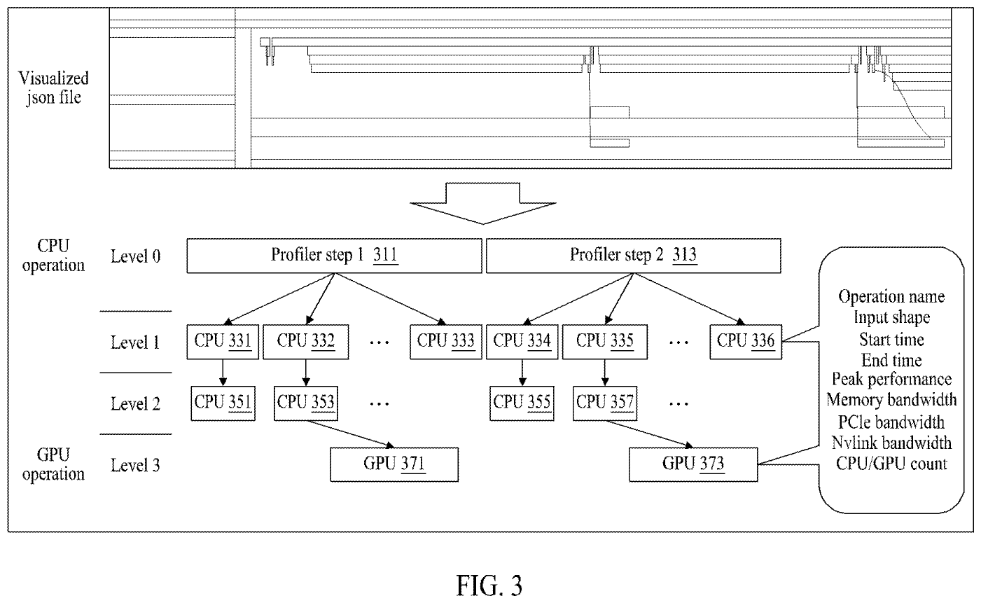

FIG. 3 illustrates an example of an operation of predicting a performance profile by adding information related to hardware to a profile result, according to one or more embodiments.

Referring to FIG. 3, a processor (e.g., the processor 200 of FIG. 1) may generate a profile result by performing profiling based on a generated class. For example, the profile result may be in the form of a javascript object notation (json) file, as non-limiting examples. The example of FIG. 3 may be a tree-type data structure generated based on a visualized json file.

The tree-type data structure may include a plurality of nodes. A node may include a plurality of levels. Level 0 may be a level of a highest node, and level 3 may be a level of a lowest node. In other embodiments, any number of nodes and node levels may be employed.

The processor 200 may represent a profiler step 1 311 and a profiler step 2 313 as a level 0 node. The processor 200 may represent level 1 CPU operations 331, 332, 333, 334, 335 or 336 as lower nodes of the profiler step 1 311 and the profiler step 2 313.

The processor 200 may represent level 2 CPU operations 351, 353, 355 or 357 as lower nodes of the level 1 CPU operations 331, 332, 333, 334, 335 or 336. The processor 200 may represent level 3 GPU operations 371 or 373 as lower nodes of the level 2 CPU operations 351, 353, 355 or 357.

The processor 200 may predict the performance of a computing system based on information related to an operation and information related to the hardware. The information related to an operation may include an operation name, an input shape, a start time and/or an end time. The information related to the hardware may include peak performance, memory bandwidth, Pcle bandwidth, Nvlink bandwidth, CPU count, and/or GPU count, as non-limiting examples.

The processor 200 may perform scale-out of a plurality of nodes and predict the new performance profile of the computing system when hardware is changed. In an example, where there is an addition (e.g., addition of a layer of a deep learning model) of an operation, the processor 200 may insert a node into the tree-type data structure or perform a rearrangement of the nodes, for example.

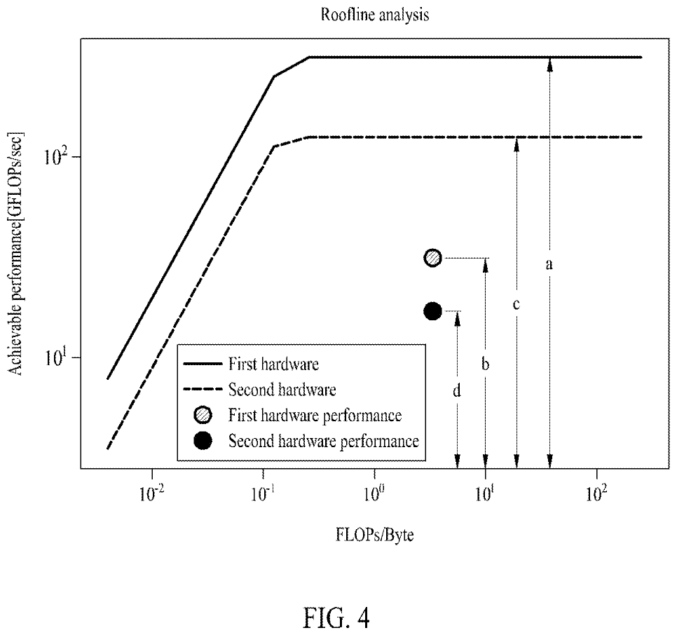

The processor 200 may calculate a change In an execution time of an operation based on an equation, and rearrange the nodes based on a calculation result. The equation will be described in detail below in reference to FIG. 4.

The processor 200 may predict the performance profile of a computing system that has not been measured by using the information related to the operation. When data having an input size different from an input size of an operation measured in advance is applied, the processor 200 may predict the performance profile of the computing system in an interpolation or extrapolation method using utilization information measured in advance.

FIG. 4 illustrates an example of a roofline model for describing a performance profile of the first hardware when employed in the computing system and a predicted performance profile of the second hardware when employed in the same computing system, according to one or more embodiments.

Referring to FIG. 4, a processor (e.g., the processor 200 of FIG. 1) may predict a performance profile of second hardware based on a performance curve of a roofline model corresponding to first hardware. The roofline model may be generated according to a profile result, utilization of the first hardware, and an operational intensity of an operation to be processed, for example.

Hereinafter, a, b, c, and d may represent the performance illustrated in FIG. 4.

The processor 200 may calculate an operational intensity OI as shown in Equation 1.

$$O I = \frac{FLOPs}{Bytes} \qquad Equation 1$$

The processor 200 may calculate the roofline model performance curve as shown in Equation 2.

Performance_{roofline}=min*(peak performance, mem bw×OI) Equation 2:

Here, mem bw may denote memory bandwidth.

The processor 200 may calculate a current utilization as shown in Equation 3.

$$Current utilization = \frac{b}{a} \qquad Equation 3$$

Here, a may denote the roofline model's peak performance curve of the first hardware, and b may denote a current performance of the first hardware.

The processor 200 may calculate predicted utilization based on Equation 4.

$$Predicted utilization = \frac{d}{c} = \frac{b}{a} \qquad Equation 4$$

Here, c may denote the roofline model's peak performance for the second hardware, and d may denote a performance of the second hardware. The proportional relationship between c and d may be based on the proportional relationship of the first hardware's relationship between a and b.

The processor 200 may predict the performance profile of the second hardware by multiplying a peak performance portion of the performance curve of the roofline model of the second hardware by the predicted utilization. The processor 200 may predict the performance of the second hardware using Equation 5.

$$Predicted perfomance = peak {performance}_{{2}_{nd} hw - roofline} \times \frac{d}{c} \qquad Equation 5$$

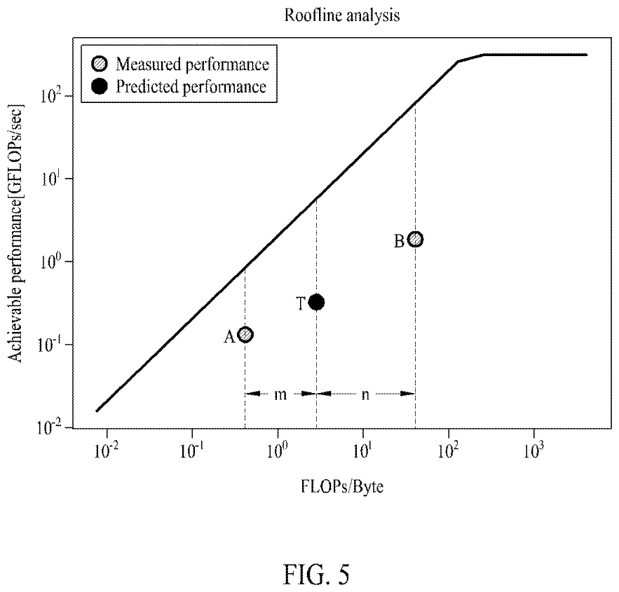

FIG. 5 illustrates an example of a graph for predicting performance, according to one or more embodiments.

Referring to FIG. 5, a processor (e.g., the processor 200 of FIG. 1) may predict a performance level of an unmeasured computing system using information related to a measured operation. When an input size is different from an input size of an operation measured in advance is applied, the processor 200 may predict a performance level of the second hardware by a process of extrapolating or interpolating based on utilization information measured in advance from known input sizes, for example.

Target utilization may be calculated based on utilization of the first hardware and an operational intensity. The processor 200 may predict the performance level of the second hardware based on the target utilization and the performance curve of the roofline model.

The processor 200 may calculate the target utilization using Equation 6.

$${Utilization}_{T} = {Utilization}_{A} + ( {Utilization}_{B} - {Utilization}_{A} ) \times \frac{m}{m + n} \qquad Equation 6$$

Here, m and n may denote operational intensity before and after an input size changes.

The processor 200 may calculate the performance level of the second hardware by multiplying the roofline model's performance curve and the target utilization. The processor 200 may predict the performance level of the second hardware by using Equation 7.

Performance_{T}=Performance_{roofline}×Utilization _{T} Equation 7:

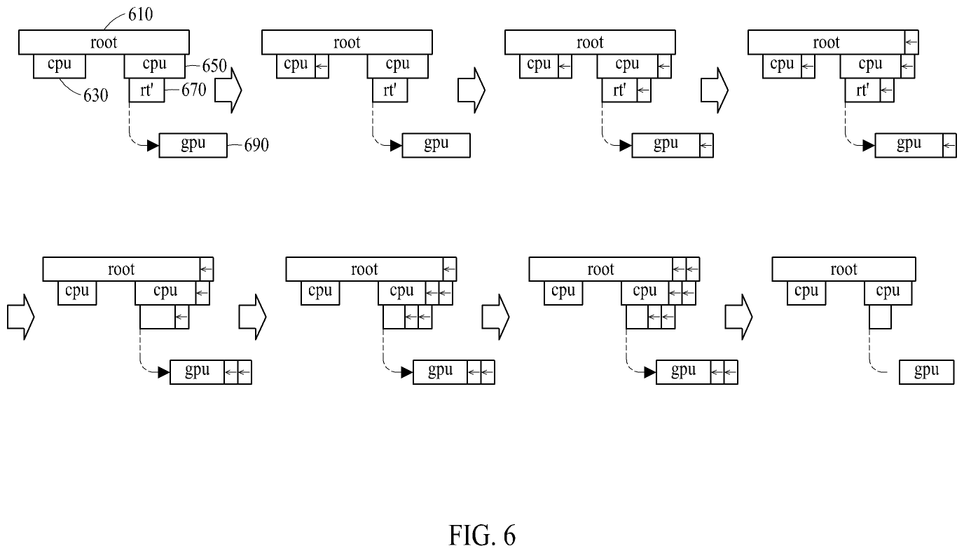

FIG. 6 illustrates an example of a process of calculating an operation time by rearranging the operations, according to one or more embodiments.

Referring to FIG. 6, a processor (e.g., the processor 200 of FIG. 1) may calculate a first changed time by changing an operation execution time of a lower node of a tree structure. The processor 200 may calculate a second changed time by changing an operation execution time of a sibling node based on the first changed time. The processor 200 may calculate the operation execution time by changing an operation execution time of an upper node based on the second changed time.

For example, the processor 200 may calculate an execution time for an operation to be performed and reflect the execution time in the lower node of the tree structure. The processor 200 may reflect the changed execution time in a length of the operation in a trace diagram.

The processor 200 may reflect the time changed in the lower node to the upper node, and may change the start time of the sibling node in the same manner. Thereafter, the processor 200 may calculate and reflect the operation time of the upper node.

The processor 200 may calculate the operation execution time by recursively repeating the above-described time reflection operation.

In the example of FIG. 6, the tree structure may include a root node 610, CPU nodes 630 and 650, a real-time node 670, and a GPU node 690. The processor 200 may reflect the operation execution time changed in the CPU node 630 to the GPU node 650, the real-time node 670, and the GPU node 690.

The processor 200 may reflect a changed result of the GPU node 690 to the real-time node 670 and CPU nodes 630 and 650 that are upper nodes.

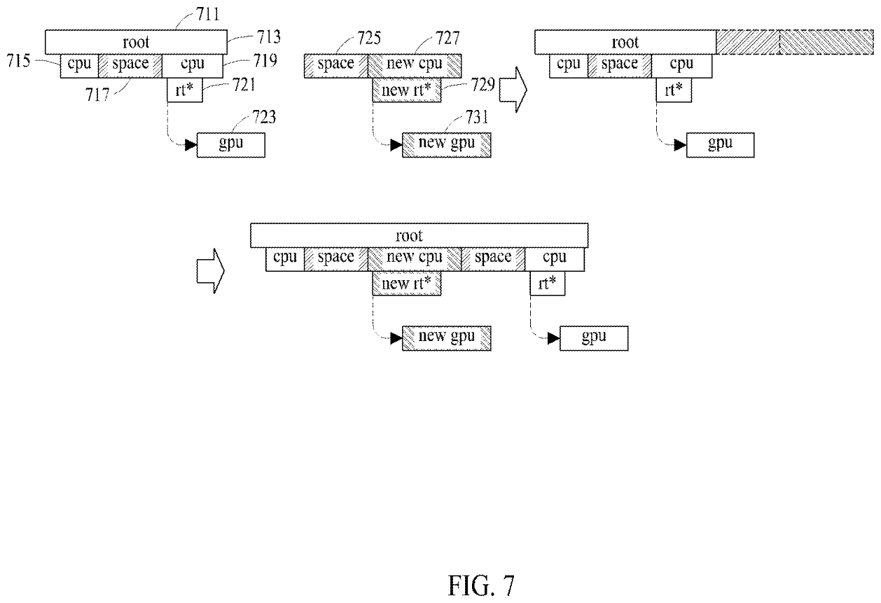

FIG. 7 illustrates an example of a process of inserting an operation, according to one or more embodiments.

Referring to FIG. 7, when an additional operation is present, a processor (e.g., the processor 200 of FIG. 1) may extend an execution time of a first node among a plurality of nodes. The processor 200 may calculate the operation execution time by inserting the additional operation between an operation of a second node that performs operation prior to the first node and an operation of the first node.

The processor 200 may perform Insertion or deletion of an operation to reflect a change in the configuration of a workload. The example of FIG. 7 may represent an operation in which the processor 200 inserts an additional operation between a CPU node 715 and a CPU node 719.

The processor 200 may generate a node corresponding to the additional operation. In the example of FIG. 7, the node corresponding to the additional operation may include a space node 725, a new CPU node 727, a new real-time node 729, and a new GPU node 731.

Empty time between operations may be expressed using a variable or a space object, and the processor 200 may calculate an average of space values of the same operation or use a value calculated through a microbenchmark.

The processor 200 may move operations starting at a time thereafter from a position where a new operation is added by the execution time of the added operation. In other words, the processor 200 may extend a root node 711 and move the start times of the space node 717, the CPU node 719, the real-time node 721, and the GPU node 723.

The processor 200 may perform the deletion of an operation by reversing the above-described process. A length (or time) of a space node or operation according to a change in the performance of the computing hardware may be changed according to a ratio of the performance or may be fixed as an absolute value. Alternatively, the length of a space node or operation may be determined using an initial profile result.

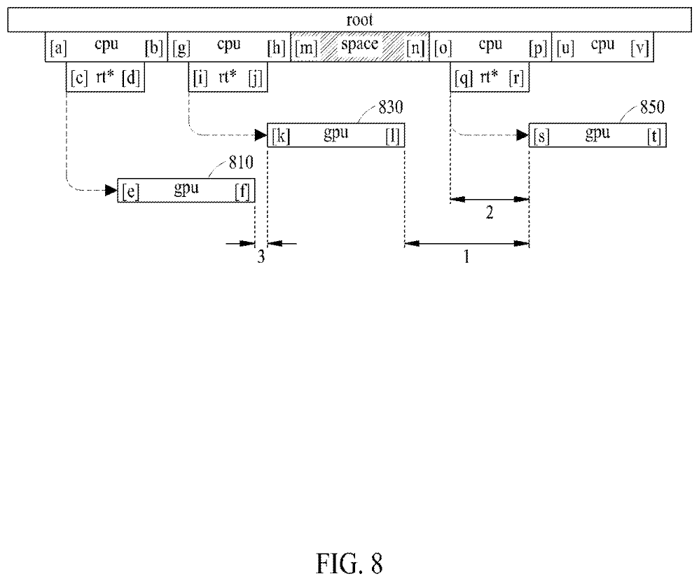

FIG. 8 illustrates an example of a process of aligning an operation, according to one or more embodiments.

Referring to FIG. 8, a processor (e.g., the processor 200 of FIG. 1) may determine a start time of an operation corresponding to a plurality of nodes based on a causal relationship between the plurality of nodes. The processor 200 may determine a start time of an operation corresponding to child nodes based on a start time of an operation corresponding to a parent node included in the plurality of nodes and a causal relationship between the child nodes of the parent node.

The processor 200 may align nodes corresponding to operations performed by computing hardware in a system configured with different hardware. For example, the processor 200 may align GPU operations as illustrated in the example of FIG. 8.

Between [q], which is a start time of a CPU operation for executing a GPU operation 850, and [s], which is a start time of the GPU operation 850, there may be a time difference as much as interval 2, and the time difference may have a positive value greater than “0”.

Interval 1, which is an interval between the end of a GPU operation 830 and the start of the GPU operation 850, may have a positive value greater than “0”.

Such as between [p] and [u], the time between CPU operations may have a value greater than or equal to “0”. When an added CPU operation is a pure CPU operation that does not accompany a GPU operation, the next CPU operation may be subsequently performed when the previous CPU operation is finished, regardless of the GPU execution time.

Interval 3, which is an interval between the end of a GPU operation 810 and the start of the GPU operation 830 executed in different components, may have a value greater than or equal to “0” when there is a causal relationship between the GPU operation 810 and the GPU operation 830, and a negative value may be assigned when there is no causal relationship. That is, the processor 200 may adjust the operation start time so that an operation with no causal relationship is performed in parallel.

The CPU or GPU described as computing hardware with reference to FIGS. 6 to 8 is merely an example, and the processor 200 may perform performance prediction and calculation of the operation execution time for other operation devices (e.g., CPU, GPU, FPGA and/or NPU), network components, and/or storage components, as non-limiting examples.

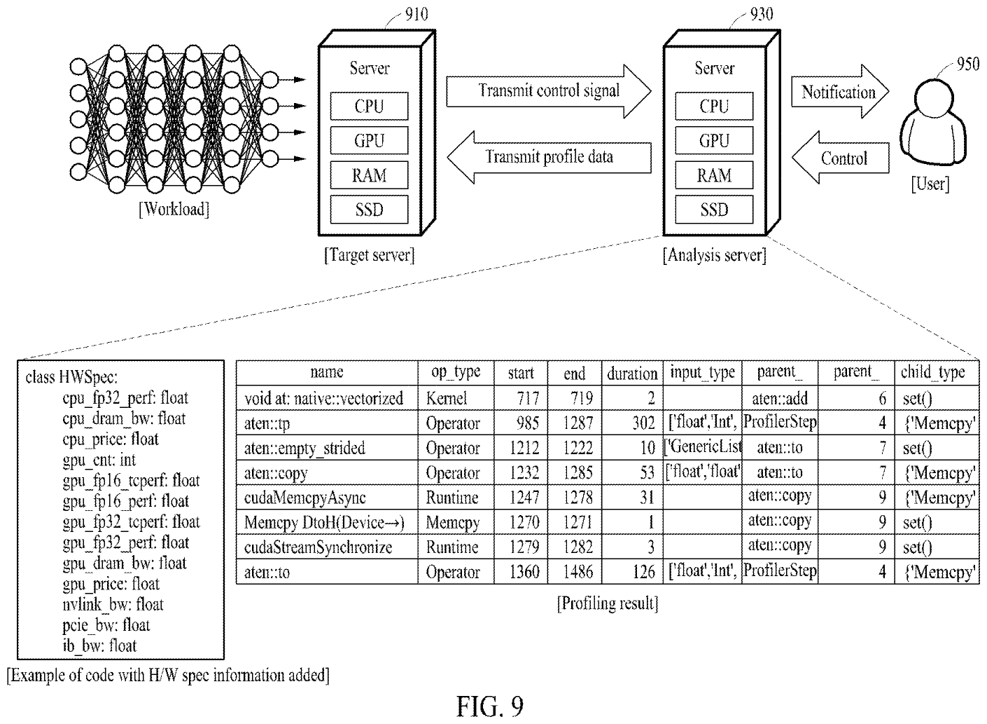

FIG. 9 illustrates an example of an implementation of performance modeling, according to one or more embodiments.

Referring to FIG. 9, a computing apparatus (e.g., the computing apparatus 10 of FIG. 1) may model the performance of a computing system. In the example of FIG. 9, the computing apparatus 10 may be implemented on an analysis server 930, and the computing system required for modeling a performance curve may be a target server 910.

The analysis server 930 may predict the performance of the target server 910 through the computing apparatus 10.

The computing apparatus 10 may perform performance modeling by receiving and processing profile data generated by the target server 910. A job to be processed by the target server 910 and the analysis server 930 may be processed by the target server 910. In an example, a job to be processed by the target server 910 and the analysis server 930 may be processed only by the target server 910.

The target server 910 or the analysis server 930 may provide a notification to a user 950. The target server 910 or the analysis server 930 may perform performance modeling based on a control signal received from the user 950.

The target server 910 or the analysis server 930 may transmit information to the user 950 in real time. A server (e.g., the target server 910 or the analysis server 930) may operate by receiving a command from the user 950 in real time.

By receiving and processing commands in real time, the server (e.g., the target server 910 or the analysis server 930) may derive performance for additional hardware, and update data generated and stored by previously set hardware according to new setting information.

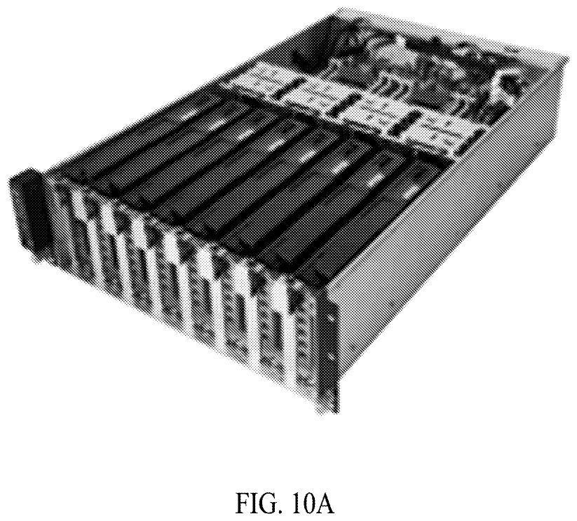

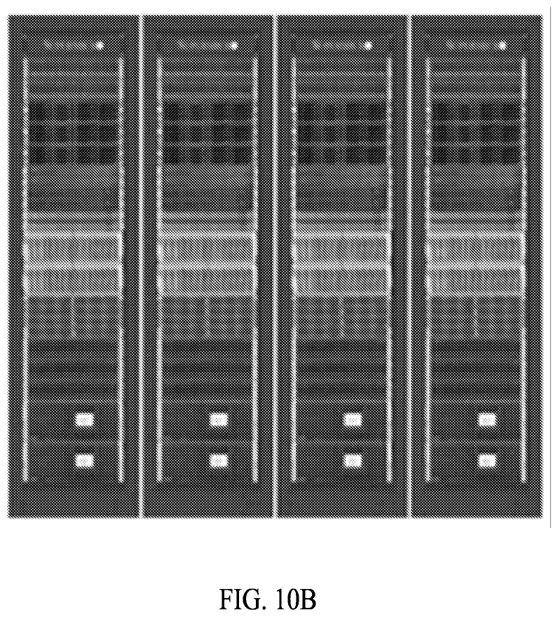

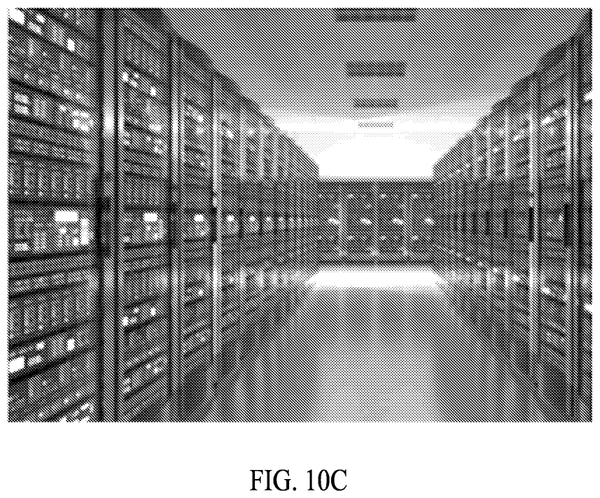

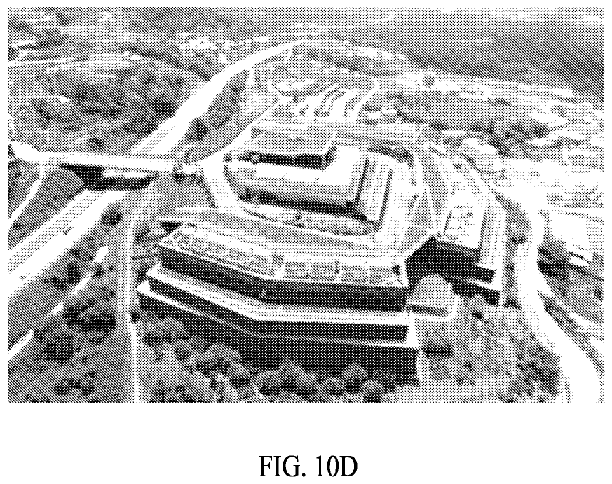

FIGS. 10A to 10D illustrate embodiments of the computing apparatus and system, according to one or more embodiments.

Referring to FIGS. 10A to 10D, a computing apparatus (e.g., the computing apparatus 10 of FIG. 1) may predict performance of various computing systems. For example, the computing systems may include the server 1010 of FIG. 10A, the server system 1020 of FIG. 10B, the server farm 1030 of FIG. 100, distributed or cloud network 1040 of FIG. 10D. According to various embodiments, while server(s), cloud, or corporate network are described, any above or below descriptions of various computing systems are also applicable for such various levels or extent of such computer systems, e.g., from a small computer system (e.g., the server 1010) to much larger and variously distributed computing systems or networks (e.g., the distributed or cloud network 1040), as non-limiting examples. In an example, any one of the server 1010, the server system 1020, the server farm 1030, distributed or cloud network 1040 may include one or both of the first hardware and the second hardware.

As another such example of the various levels or extents of the computing apparatus 10 may provide an investment guide by predicting performance of high performance computing (HPC), a supercomputer, a data center, or a cloud system, as non-limiting examples. In one example, any of such computing systems may also be or include the computing apparatus 10 and perform performance modeling of another one or more various levels or extents of the computing systems.

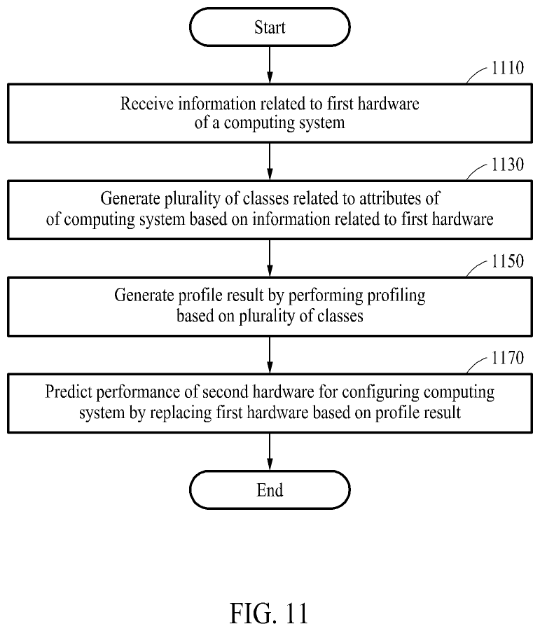

FIG. 11 illustrates an example of a method of predicting a performance curve of a hardware system according to one or more embodiments.

Referring to FIG. 11, in operation 1110, a receiver (e.g., the receiver 100 of FIG. 1) may obtain or receive information related to hardware of a computing system. The hardware information may include the hardware's driving frequency, peak performance, cache memory capacity, cache memory bandwidth, memory frequency, memory capacity, memory bandwidth, storage capacity, storage bandwidth, bandwidth between hardware and other hardware, bandwidth between hardware and memory, and/or network bandwidth, as non-limiting examples. The hardware related to the computing system may be referred to as the first hardware.

In operation 1130, the processor 200 may generate a plurality of classes related to attributes of the computing system based on information related to the first hardware. In operation 1150, the processor 200 may perform profiling to generate a profile result based on the plurality of classes.

In operation, 1170, the processor 200 may predict a performance profile of the second hardware in another configuration of the computing system by using the profile result from first hardware.

The processor 200 may predict the performance profile of the second hardware based on a performance curve of a roofline model corresponding to the first hardware according to the profile result, utilization of the first hardware, and an operational intensity of an operation to be processed.

The processor 200 may calculate a target utilization based on the utilization of the first hardware and the operational intensity. The processor 200 may predict the performance of the second hardware based on the target utilization and the performance, e.g., performance curve, of the roofline model.

The processor 200 may predict the performance of the second hardware based on the target utilization and the performance of the roofline model.

The processor 200 may predict the performance of the second hardware by performing interpolation or extrapolation based on the target utilization and the performance of the roofline model.

The second hardware may perform an operation based on a tree structure including a plurality of nodes corresponding to different operations. The processor 200 may calculate an operation execution time of the plurality of nodes based on the tree structure including the plurality of nodes.

The processor 200 may calculate a first changed time by changing an operation execution time of a lower node of the tree structure. The processor 200 may calculate a second changed time by changing an operation execution time of a sibling node based on the first changed time. The processor 200 may calculate the operation execution time by changing an operation execution time of an upper node based on the second changed time.

When an additional operation is present, the processor 200 may extend the execution time of the first node among the plurality of nodes. The processor 200 may calculate the operation execution time by inserting the additional operation between an operation of a second node that performs operation prior to the first node and an operation of the first node.

The processor 200 may determine a start time of an operation corresponding to the plurality of nodes based on a causal relationship of the operations between the plurality of nodes. The processor 200 may determine a start time of an operation corresponding to child nodes based on a start time of an operation corresponding to a parent node included in the plurality of nodes and a causal relationship between the child nodes of the parent node.

The processors, receivers, memories, and servers described herein and disclosed herein described with respect to FIGS. 1-11 are implemented by or representative of hardware components. As described above, or in addition to the descriptions above, hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-11 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. As described above, or in addition to the descriptions above, examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-rEs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A computing apparatus, the apparatus comprising:
a processor configured to:
generate a plurality of classes related to properties of a computing system based on received information related to a first hardware of the computing system;
generate a profile result based on the plurality of classes; and
predict a performance of second hardware in the computing system in place of the first hardware, wherein the prediction is based on the profile result.

2. The apparatus of claim 1, wherein the information comprises driving frequency, a peak performance, a cache memory capacity, a cache memory bandwidth, a memory frequency, a memory capacity, a memory bandwidth, a storage capacity, a storage bandwidth of the first hardware, a bandwidth between the first hardware and other hardware, a bandwidth between the first hardware and a memory, and/or a network bandwidth.

3. The apparatus of claim 1, wherein, for the prediction of the performance of the second hardware, the processor is configured to:
predict the performance of the second hardware based on a performance curve of a roofline model corresponding to the first hardware according to the profile result, a utilization of the first hardware, and an operational intensity of an operation to be processed.

4. The apparatus of claim 3, wherein, for the prediction of the performance of the second hardware, the processor is configured to:
calculate a target utilization based on the utilization of the first hardware and the operational intensity; and
predict the performance of the second hardware based on the target utilization and the performance curve of the roofline model.

5. The apparatus of claim 4, wherein, for the prediction of the performance of the second hardware, the processor is configured to:
predict the performance of the second hardware by performing interpolation or extrapolation based on the target utilization and the performance curve of the roofline model.

6. The apparatus of claim 1, wherein, for the prediction of the performance of the second hardware, the processor is configured to calculate an operation execution time of multiple nodes, of a plurality of nodes corresponding to different operations, of a tree structure, an operation of which having been performed by the second hardware.

7. The apparatus of claim 6, wherein, for the prediction of the performance of the second hardware, the processor is configured to:
calculate a first changed time by changing an operation execution time of a lower node of the multiple nodes;
calculate a second changed time by changing an operation execution time of a sibling node of the multiple nodes based on the first changed time; and
calculate the operation execution time by changing an operation execution time of an upper node of the multiple nodes based on the second changed time.

8. The apparatus of claim 6, wherein, for the prediction of the performance of the second hardware, the processor is configured to:
extend an execution time of a first node among the multiple nodes responsive to an addition of a new operation to the plurality of nodes; and
calculate the operation execution time by inserting the new operation between an operation of a second node, of the multiple nodes, that performs an operation prior to the first node and an operation of the first node.

9. The apparatus of claim 6, wherein, for the prediction of the performance of the second hardware, the processor is configured to:
determine a start time of an operation corresponding to the multiple nodes based on a causal relationship of the operations between the multiple nodes.

10. The apparatus of claim 6, wherein, for the prediction of the performance of the second hardware, the processor is configured to:
determine a start time of an operation corresponding to child nodes, of the multiple nodes, based on a start time of an operation corresponding to a parent node, of the multiple nodes, and a causal relationship between the child nodes of the parent node.

11. A processor-implemented method, the method comprising:
generating a plurality of classes related to properties of a computing system based on information related to a first hardware of the computing system;
performing profiling based on the plurality of classes; and
predicting performance of second hardware in the computing system in place of the first hardware, wherein the predicting is based on the profiling.

12. The method of claim 11, wherein the information comprises:
driving frequency, peak performance, cache memory capacity, cache memory bandwidth, memory frequency, memory capacity, memory bandwidth, storage capacity, storage bandwidth of the first hardware, bandwidth between the first hardware and other hardware, bandwidth between the first hardware and memory, and/or network bandwidth.

13. The method of claim 11, wherein the predicting comprises:
predicting the performance of the second hardware based on a performance curve of a roofline model corresponding to the first hardware according to the profiling, a utilization of the first hardware, and an operational intensity of an operation to be processed.

14. The method of claim 13, wherein the predicting of the performance of the second hardware comprises:
calculating a target utilization based on the utilization of the first hardware and the operational intensity; and
predicting the performance of the second hardware based on the target utilization and the performance curve of the roofline model.

15. The method of claim 14, wherein the predicting of the performance of the second hardware further comprises:
predicting the performance of the second hardware by performing interpolation or extrapolation based on the target utilization and the performance curve of the roofline model.

16. The method of claim 11, wherein, for the predicting the performance of the second hardware, the predicting comprises:
calculating an operation execution time of multiple nodes, of a plurality of nodes, of a tree structure, an operation of which having been performed by the second hardware.

17. The method of claim 16, wherein the calculating of the operation execution time of the multiple nodes comprises:
calculating a first changed time by changing an operation execution time of a lower node of the multiple nodes;
calculating a second changed time by changing an operation execution time of a sibling node of the multiple nodes based on the first changed time; and
calculating the operation execution time by changing an operation execution time of an upper node of the multiple nodes based on the second changed time.

18. The method of claim 16, wherein the calculating of the operation execution time of the multiple nodes comprises:
extending an execution time of a first node among the multiple nodes responsive to an addition of a new operation to the plurality of nodes; and
calculating the operation execution time by inserting the new operation between an operation of a second node, of the multiple nodes, that performs an operation prior to the first node and an operation of the first node.

19. The method of claim 16, wherein the calculating of the operation execution time of the plurality of nodes comprises:
determining a start time of an operation corresponding to the multiple nodes based on a causal relationship of the operations between the multiple nodes.

20. The method of claim 16, wherein the calculating of the operation execution time of the plurality of nodes comprises:
determining a start time of an operation corresponding to child nodes, of the multiple nodes, based on a start time of an operation corresponding to a parent node, of the multiple nodes, and a causal relationship between the child nodes of the parent node.
